(19) United States
(12) Patent Application Publication
(10) Pub. No.: US 2025/0233003 A1
(43) Pub. Date: Jul. 17, 2025

(54) JIG AND DIE ATTACH APPARATUS FOR INCLUDING THE SAME

(71) Applicant: Samsung Electronics Co., Ltd., Suwon-si (KR)

(72) Inventor: Sangyoung JO, Suwon-si (KR)

(73) Assignee: Samsung Electronics Co., Ltd., Suwon-si (KR)

(21) Appl. No.: 18/779,705

(22) Filed: Jul. 22, 2024

(30) Foreign Application Priority Data
Jan. 12, 2024 (KR) 10-2024-0005454

(51) Int. Cl. H01L 21/683

(52) U.S. Cl. CPC H01L 21/6838

(57) ABSTRACT

A jig for a die attach device may include at least one mount block including at least two holding surfaces, each of the at least two holding surfaces configured to, hold a package substrate on which a semiconductor die is mounted, and rotate around a rotation shaft extending along a first horizontal direction, and a cleaning device configured to clean a target holding surface among the at least two holding surfaces, the target holding surface being a holding surface which faces the cleaning device among the at least two holding surfaces.

### CROSS-RELATED APPLICATION

This U.S. non-provisional application claims the benefit of priority under 35 USC § 119 to Korean Patent Application No. 10-2024-0005454, filed on Jan. 12, 2024 in the Korean Intellectual Property Office (KIPO), the contents of which are herein incorporated by reference in their entirety.

### BACKGROUND

Various example embodiments relate to a jig, a die attaching apparatus including the same, a system including the same, and/or a method of operating the jig, etc. More specifically, one or more example embodiments relate to a jig configured to support a package substrate on which a semiconductor die is mounted, a die attaching apparatus including the jig, a system including the jig, and/or a method of operating the jig, etc.

In general, a die attaching apparatus may attach a semiconductor die to a package substrate. The die attaching apparatus may include a mount head configured to hold the semiconductor die and a jig configured to support the package substrate.

When particles are deposited and/or interposed between the jig and the package substrate, the semiconductor die may not be accurately and/or completely attached to the package substrate. Therefore, periodic visual inspections are performed to check whether particles and/or debris exist between the jig and the package substrate. Since the periodic visual inspection should be performed while the die attach process is stopped, delays are experienced in the die attach process.

In addition, when it is confirmed that particles and/or debris may exist between the jig and the package substrate, an interruption of the die attachment process may be desired and/or required to clean the jig and/or package substrate. In a state in which the die attachment process is stopped, a separate cleaning process for removing particles and/or debris is performed. Thus, the die attachment process time may be further increased.

### SUMMARY

Various example embodiments provide a jig for a die-attach apparatus that may be capable of removing particles and/or debris without interrupting a die-attach process.

Various example embodiments also provide a die attachment device including the above-described jig.

According to one or more example embodiments, there may be provided a jig for a die attaching apparatus. The jig may include at least one mount block including at least two holding surfaces, each of the at least two holding surfaces configured to, hold a package substrate on which a semiconductor die is mounted, and rotate around a rotation shaft extending along a first horizontal direction, and a cleaning device configured to clean a target holding surface among the at least two holding surfaces, the target holding surface being a holding surface which faces the cleaning device among the at least two holding surfaces.

According to one or more example embodiments, there may be provided a jig for a die attaching apparatus. The jig may include a base block including a receiving groove, the receiving groove configured to hold a semiconductor die, a mount block including at least two holding surfaces, the at least two holding surfaces configured to rotate along a rotation shaft extending along a first horizontal direction, and hold a package substrate on which the semiconductor die is mounted, a rotation device configured to rotate the mount block around the rotation shaft, and a cleaning device included in the receiving groove, the cleaning device configured to clean a target holding surface, the target holding surface being a holding surface facing the cleaning device among the at least two holding surfaces.

According to one or more example embodiments, there may be provided a die attachment apparatus. The die attaching apparatus may include a mount head configured to mount a semiconductor die to a package substrate, a mount block including at least two holding surfaces, the at least two holding surfaces configured to rotate along a rotation shaft, and to hold the package substrate under the mount head, the rotation shaft extending along a first horizontal direction, and a cleaning device configured to clean a target holding surface, the target holding surface being a holding surface facing the cleaning device among the at least two holding surfaces.

According to one or more example embodiments, one of the remaining holding surfaces except for the holding surface holding the package substrate may be cleaned by the cleaning module. Since the operation of the cleaning module may be performed while the die attach process may be performed, it may not be desired and/or necessary to stop a die attach process to clean and/or remove particles, debris, etc. Accordingly, the efficiency of the die attach process may be improved, the time for performing the die attach process may be decreased, and/or the success rate of the die attaching process may be increased, etc.

### BRIEF DESCRIPTION OF THE DRAWINGS

Various example embodiments will be more clearly understood from the following detailed description taken in conjunction with the accompanying drawings. FIGS. 1 to 15 represent non-limiting, example embodiments as described herein.

FIG. 1 is a cross-sectional view illustrating a die attaching apparatus in accordance with at least one example embodiment;

FIG. 2 is a cross-sectional view taken along a line A-A′ in FIG. 1 according to at least one example embodiment;

FIG. 3 is a plan view showing a cleaning module of the die attaching apparatus shown in FIG. 1 according to at least one example embodiment;

FIG. 4 is a cross-sectional view taken along a line B-B′ of FIG. 3 according to at least one example embodiment;

FIG. 5 is a plan view showing a first mount block of the die attachment device shown in FIG. 1 according to at least one example embodiment;

FIGS. 6 to 10 are cross-sectional views sequentially illustrating an operation of the die attaching apparatus illustrated in FIG. 1 according to at least one example embodiment;

FIG. 11 is a cross-sectional view illustrating a cleaning module of a die attaching apparatus in accordance with at least one example embodiment;

FIG. 12 is a cross-sectional view illustrating a cleaning module of a die attaching apparatus in accordance with at least one example embodiment;

FIG. 13 is a cross-sectional view illustrating a die attaching apparatus in accordance with at least one example embodiment;

FIG. 14 is a cross-sectional view illustrating a die attaching apparatus in accordance with at least one example embodiment; and

FIG. 15 is a cross-sectional view illustrating a die attaching apparatus in accordance with at least one example embodiment.

### DETAILED DESCRIPTION

Hereinafter, various example embodiments will be explained in detail with reference to the accompanying drawings.

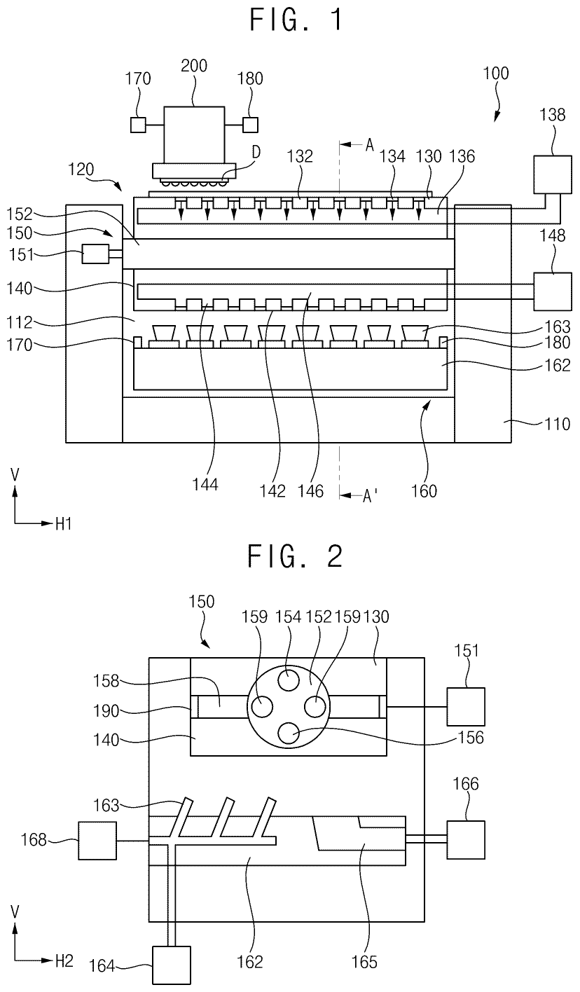

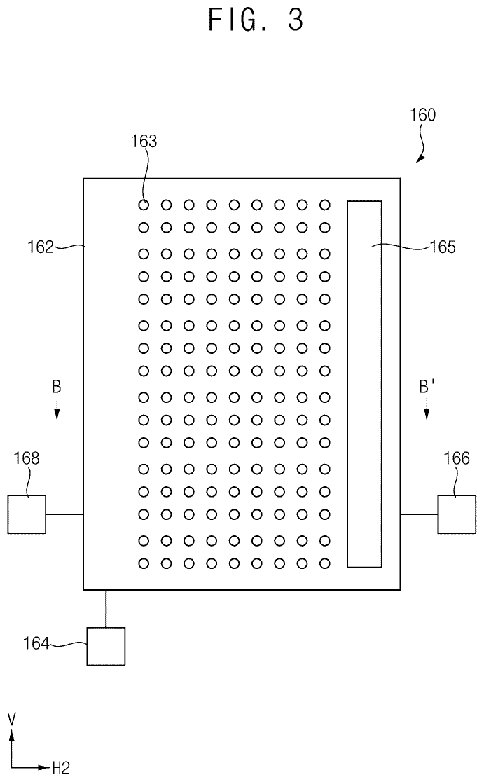

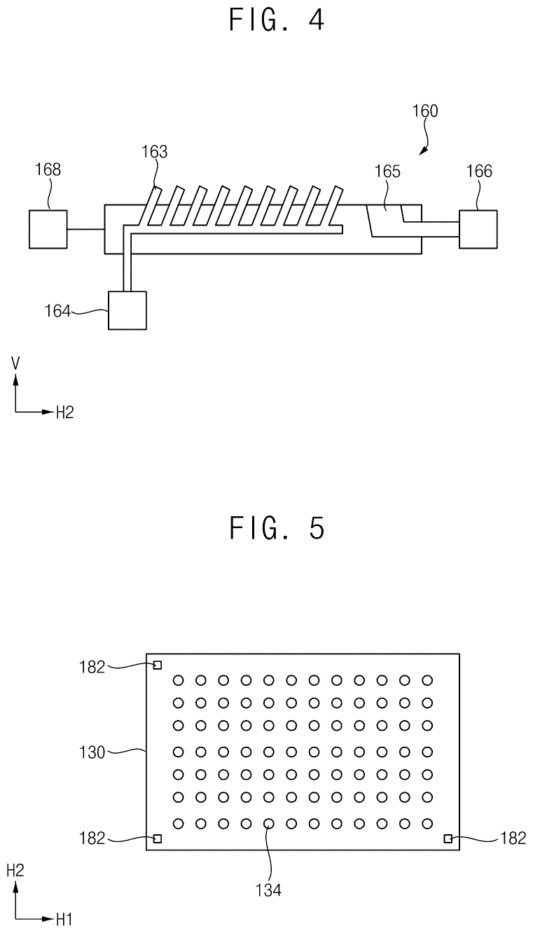

FIG. 1 is a cross-sectional view showing a die attachment device in accordance with at least one example embodiment, FIG. 2 is a cross-sectional view taken along a line A-A′ of FIG. 1 in accordance with at least one example embodiment, FIG. 3 is a plan view showing a cleaning module of the die attachment device shown in FIG. 1 in accordance with at least one example embodiment, FIG. 4 is a cross-sectional view taken along a line B-B′ of FIG. 3 in accordance with at least one example embodiment, and FIG. 5 is a plan view showing a first mount block of the die attachment device shown in FIG. 1 in accordance with at least one example embodiment.

Referring to FIGS. 1 to 5, a die attach apparatus 100 of one or more example embodiments may include a mount head 200 and/or a jig, etc., but the example embodiments are not limited thereto, and for example, the die attach apparatus 100 may include a greater or lesser number of constituent components, etc. The mount head 200 may hold a semiconductor die D. The jig may be arranged under the mount head 200 in a vertical direction V. The jig may hold a package substrate S on which the semiconductor die D may be mounted. The jig may include a base block 110, a mount block 120, a rotating module 150 (e.g., a rotator, a rotation device, rotation motor, etc.), and/or a cleaning module 160 (e.g., a cleaner, a cleaning device, etc.), but is not limited thereto.

The base block 110 may be arranged under the mount head 200 in the vertical direction V. In some example embodiments, the base block 110 may have a rectangular parallelepiped shape, but is not limited thereto. The base block 110 may include at least one receiving groove 112, etc. The receiving groove 112 may be formed on the upper surface of the base block 110 to receive the mount block 120, the rotation module 150 (e.g., rotator, rotation device, rotation motor, etc.), and/or the cleaning module 160, etc., but is not limited thereto. In some example embodiments, the receiving groove 112 may have a rectangular parallelepiped shape, but may not be limited thereto.

The mount block 120 may be received in the receiving groove 112 of the base block 110. For example, the mount block 120 may be received in the receiving groove 112 to be rotatable with respect to a first horizontal direction H1, but is not limited thereto. The rotation module 150 may rotate the mount block 120 with respect to a rotation shaft 152 which extends along the first horizontal direction H1. The mount block 120 may hold the package substrate S.

In some example embodiments, the mount block 120 may include a plurality of mount blocks, such as a first mount block 130 and a second mount block 140, etc. In FIG. 1, the first mount block 130 may be arranged on the second mount block 140, but is not limited thereto. Since the rotation module 150 may rotate the first mount block 130 and the second mount block 140 around an axis extending along the first horizontal direction H1, e.g., rotate the first mount block 130 and the second mount block 140 around the rotation shaft 152, the positions of the first mount block 130 and the second mount block 140 may be changed. That is, the second mount block 140 may be arranged above the first mount block 130 directly under the mount head 200, or vice versa.

In some example embodiments, any of the first mount block 130 and the second mount block 140 may hold the package substrate S (e.g., a semiconductor package substrate, etc.). For example, the second mount block 140 may be located below the first mount block 130, and while the mount head 200 attaches and/or mounts the semiconductor die D to the package substrate S on the first mount block 130, the cleaning module 160 may clean the second mount block 140 to remove particles and/or debris from the second mount block 140 while it is not directly under the mount head 200. In contrast, when the second mount block 140 is located on top of the first mount block 130, the mount head 200 may attach and/or mount the semiconductor die D to the package substrate S on the second mount block 140, and the cleaning module 160 may clean the first mount block 130 to remove particles and/or debris from the first mount block 130. As described above, since both the first mount block 130 and the second mount block 140 should have a structure capable of holding the package substrate S in the same manner, the first mount block 130 and the second mount block 140 may have shapes and sizes compatible with each other, but are not limited thereto. That is, the first mount block 130 and the second mount block 140 may have substantially the same shape and size, but the example embodiments are not limited thereto. Additionally, while FIG. 1 illustrates two mount blocks, the example embodiments are not limited thereto, and the die attach apparatus 100 may include a greater number of mount blocks, a single mount block, etc.

The first mount block 130 may have a rectangular parallelepiped shape, but is not limited thereto. The first mount block 130 may have a first holding surface 132 configured to hold the package substrate S. When the first mount block 130 is positioned above the second mount block 140, the first holding surface 132 may be an upper surface of the first mount block 130.

In some example embodiments, the first mount block 130 may hold the package substrate S using a vacuum (e.g., by applying negative pressure, etc.). Accordingly, the first mount block 130 may include a first vacuum pump 138, a first vacuum line 136, and/or a plurality of first vacuum holes 134, but is not limited thereto. The first vacuum line 136 may extend in the first horizontal direction H1 within the first mount block 130, but is not limited thereto, and may extend in other directions, etc. The first vacuum pump 138 may be connected to the first vacuum line 136 to provide the vacuum to the first vacuum line 136. The first vacuum holes 134 may be formed in the first holding surface 132. The first vacuum holes 134 may be connected to the first vacuum line 136 to receive the vacuum from the vacuum pump 138. The first vacuum holes 134 may be connected to the first vacuum line 136. In some example embodiments, the first vacuum holes 134 may be arranged at a uniform interval, but are not limited thereto.

The second mount block 140 may have a rectangular parallelepiped shape, but is not limited thereto. The second mount block 140 may have a second holding surface 142 configured to hold the package substrate S. When the second mount block 140 may be located below the first mount block 130, the second holding surface 142 may be a lower surface of the second mount block 140.

In some example embodiments, the second mount block 140 may hold the package substrate S using a vacuum (e.g., by applying negative pressure, etc.). Accordingly, the second mount block 140 may include a second vacuum pump 148, a second vacuum line 146, and/or a plurality of second vacuum holes 144, etc., but is not limited thereto. The second vacuum line 146 may extend in the first horizontal direction H1 in the second mount block 140, but is not limited thereto and may extend along other directions. The second vacuum pump 148 may be connected to the second vacuum line 146 to provide the vacuum to the second vacuum line 146. The second vacuum holes 144 may be formed in the second holding surface 142. The second vacuum holes 144 may be connected to the second vacuum line 146 to receive the vacuum (e.g., negative air pressure, etc.) from the vacuum pump 148. In some example embodiments, the second vacuum holes 144 may be arranged at a uniform interval, but are not limited thereto.

The rotation module 150 may rotate the first mount block 130 and the second mount block 140 around an axis extending along the first horizontal direction H1. In particular, the rotation module 150 may rotate the first mount block 130 and the second mount block 140 by approximately 180° around an axis extending along the first horizontal direction H1, but the example embodiments are not limited thereto, and for example, when there are three mount blocks, the rotation module 150 may rotate the mount blocks by approximately 120° increments, etc. Thus, when the rotation module 150 rotates the first mount block 130 and the second mount block 140 by approximately 180°, one of the first mount block 130 and the second mount block 140 may be used for a die attach process, and the other may be cleaned using the cleaning module 160. Accordingly, the first mount block 130 and the second mount block 140 may be located at approximately 180° intervals around the rotation module 150 in the first horizontal direction H1.

In at least one example embodiment, the rotation module 150 may include a rotation shaft 152, a rotation actuator 151, and/or a connection block 158, etc., but is not limited thereto.

The rotation actuator 151 may be connected to the rotation shaft 152 to transmit a rotation force to the rotation shaft 152. In some example embodiments, the rotation actuator 151 may include a motor, but is not limited thereto.

The rotation shaft 152 may be arranged in the first horizontal direction H1 in the receiving groove 112 of the base block 110. Both ends of the rotation shaft 152 may be rotatably supported on both sidewalls of the receiving groove 112. Accordingly, the rotation shaft 152 may be rotated around the first horizontal direction Hl in the receiving groove 112.

In some example embodiments, the rotation shaft 152 may include a first vacuum passage 154 and/or a second vacuum passage 156, etc. The first vacuum passage 154 may extend in the first horizontal direction Hl inside the rotation shaft 152. The first vacuum passage 154 may connect the first vacuum pump 138 to the first vacuum line 136. The second vacuum passage 156 may extend in the first horizontal direction Hl inside the rotation shaft 152. The second vacuum passage 156 may connect the second vacuum pump 148 to the second vacuum line 146. The first vacuum passage 154 and the second vacuum passage 156 may be symmetrical with respect to an axial direction of the rotation shaft 152, but are not limited thereto. According to at least one example embodiment, the second vacuum pump 148 may be omitted and a single vacuum pump may be used with both the first vacuum passage 154 and the second vacuum passage 156, etc.

In some example embodiments, the rotation shaft 152 may be connected to the first mount block 130 and the second mount block 140, etc. Therefore, the first mount block 130 and the second mount block 140 may be rotated around an imaginary axis extending along the first horizontal direction Hl due to the rotation of the rotation shaft 152, or in other words, the first mount block 130 and the second mount block 140 may rotate around the rotation shaft 152. In particular, in FIG. 1, an upper portion (e.g., a first portion) of the rotation shaft 152 may be connected to the first mount block 130. A lower portion (e.g., a second portion) of the rotation shaft 152 may be connected to the second mount portion, etc. In this case, a gap may be formed between the first mount block 130 and the second mount block 140.

To reinforce the connection between the rotation shaft 152 and the first and second mount blocks 140, a connection block 158 may be between the rotation shaft 152 and the first and second mount blocks 140. The connection block 158 may be located in a gap between the first mount block 130 and the second mount block 140, but is not limited thereto.

Additionally, a first fixing pin 159 and a second fixing pin 159 may be inserted into the rotation shaft 152 (e.g., a rotary shaft, etc.) to connect the rotary shaft 152 and the connection block 158. In particular, the first fixing pin 159 and the second fixing pin 159 may be arranged in the rotation shaft 152 along the first horizontal direction HI to fix the rotation shaft 152 to the connection block 158. The first fixing pin 159 and the second fixing pin 159 may be symmetrical about the axial direction of the rotation shaft 152, but are not limited thereto.

The cleaning module 160 may be arranged in the receiving groove 112 of the base block 110, but is not limited thereto. For example, the cleaning module 160 may be located under the mount block 120, but is not limited thereto. As described above, while the die attach process is performed on one mount block, e.g., the first mount block 130, the cleaning module 160 may clean the other mount block, e.g., the second mount block 140, etc., to remove particles and/or debris from the other mount block, e.g., the second mount block 140.

In some example embodiments, the cleaning module 160 may include a cleaning block 162, a plurality of injection nozzles 163, an air source 164, a horizontal actuator 168, and/or a suction pump 166, etc., but is not limited thereto.

The cleaning block 162 may be arranged in the receiving groove 112 under the mount block 120, but is not limited thereto. For example, the cleaning block 162 may be movably arranged in the receiving groove 112 along a second horizontal direction H2 substantially orthogonal to the first horizontal direction H1, but is not limited thereto. As another example, the cleaning block 162 may be movably arranged in the first horizontal direction H1 or a direction forming an acute angle with the first horizontal direction H1, etc.

The horizontal actuator 168 may move the cleaning block 162 in the second horizontal direction H2. In some example embodiments, the horizontal actuator 168 may include a motor, a cylinder, etc., but may not be limited thereto.

The injection nozzles 163 (e.g., air nozzles, etc.) may be arranged on the upper surface of the cleaning block 162 to inject (e.g., eject, emit, expel, blow, etc.) air onto the second holding surface 142 of the second mount block 140. In other words, the air nozzles 163 of the cleaning block 162 may blow air onto a target holding surface among the plurality of holding surfaces of the die attach apparatus 100. The air source 164 (e.g., a fan, a blower, an air compressor, etc.) may be connected to the injection nozzles 163 to supply the air to the injection nozzles 163.

In some example embodiments, the injection nozzles 163 may be arranged to be inclined and/or angled with respect to the vertical direction V. For example, if the injection nozzles 163 are parallel to the vertical direction V, the air is blown from the injection nozzles 163 along the vertical direction V may cause the particles and/or debris blown from the second holding surface 142 to reattach (e.g., re-settle, etc.) onto the second holding surface 142. Accordingly, the injection nozzles 163 may be angled with respect to the vertical direction Vin order to allow the air to be sprayed at an angle with respect to the vertical direction V and the surface of the second holding surface 142, thereby decreasing and/or preventing the second holding surface 142 from being re-contaminated by the particles and/or debris.

The cleaning block 162 may further include at least one suction groove 165, etc. The suction groove 165 may be formed on the upper surface of the cleaning block 162, but is not limited thereto. For example, the suction groove 165 may be located on the opposite side of the injection nozzle 163, or in other words, a different side of the cleaning block 162 than the injection nozzle 163. The suction groove 165 may be connected to the suction pump 166. A vacuum (e.g., negative air pressure) may be provided by the suction pump 166 to the suction groove 165. Accordingly, the particles and/or debris separated from the second holding surface 142 by the air injected from the injection nozzle 163 may be removed (e.g., suctioned) through the suction groove 165 by the vacuum generated by the suction pump 166. In some example embodiments, the suction groove 165 may be elongated along the first horizontal direction H1, but is not limited thereto.

In this way, while the die attach process may be performed on the first mount block 130, the cleaning module 160 may clean the second mount block 140 using air. Therefore, vibrations may be generated in the second mount block 140 due to the pressure of the air. When the vibration of the second mount block 140 is transmitted to the first mount block 130, it may not be possible to accurately attach, mount, and/or hold the semiconductor die D to the package substrate S on the first holding surface 132 of the first mount block 130.

To decrease and/or prevent vibrations from interfering with the mounting of the semiconductor die D to the package substrate S on the first holding surface 132, at least one damper 190 may be interposed between the first mount block 130 and the second mount block 140. The damper 190 may decrease and/or block transmission of the vibration between the first mount block 130 and the second mount block 140, etc. For example, the damper 190 may have a structure using a spring, a shock absorber, etc., but is not limited thereto.

In addition, the die attachment apparatus 100 of one or more example embodiments may further include at least one vision camera 170, etc. The vision camera 170 (e.g., image sensor, etc.) may photograph and/or videotape the holding surface cleaned by the cleaning module 160 to obtain an image and/or video of the holding surface. It may be possible to check whether the particles and/or debris has been removed from the image of the holding surface. In some example embodiments, the vision camera 170 may be provided in the cleaning module 160 and/or the mount head 200, etc., but is not limited thereto.

Further, as described above, since the first mount block 130 and the second mount block 140 may be rotated approximately 180° by the rotation module 150, it may be desired and/or necessary to check whether the first mount block 130 and the second mount block 140 may be positioned horizontally in order to perform the accurate die attach process. To this end, the die attach device 100 may further include at least one sensor 180 configured to measure the horizontality and/or angle of each of the first and second holding surfaces 132 and 142, or in other words, the sensor 180 may determine whether the first and/or second holding surfaces 132 and 142 are horizontally level.

Marks 182 (e.g., visual marks, visual indicators, etc.) recognized by the sensor 180 may be arranged on the first holding surface 132 of the first mount block 130 and the second holding surface 142 of the second mount block 140, etc. For example, the marks 182 may be located adjacent to three of the corners of the first holding surface 132 and the second holding surface 142, but the example embodiments are not limited thereto. In particular, the three marks 182 may be located in the first horizontal direction H1 and the second horizontal direction H2. By detecting the distance between the two marks 182 located in the first horizontal direction H1 and the distance between the two marks 182 located in the second horizontal direction H2, the horizontality of the first holding surface 132 and the second holding surface 142 may be confirmed and/or determined. In some example embodiments, the sensor 180 may be provided in the mount head 200 and/or the cleaning module 160, but is not limited thereto.

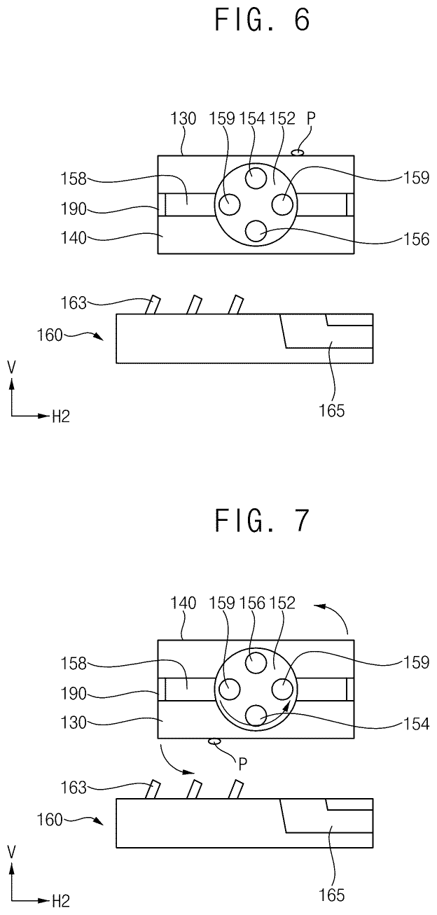

FIGS. 6 to 10 are cross-sectional views sequentially illustrating an operation of the die attaching apparatus illustrated in FIG. 1 according to some example embodiments.

Referring to FIG. 6, in a state in which the first mount block 130 may be arranged on the second mount block 140, the particles and/or debris P may exist in the first holding surface 132 of the first mount block 130.

Referring to FIG. 7, the rotation module 150 may rotate the first mount block 130 and the second mount block 140 by approximately 180°. Accordingly, the first mount block 130 on which the particles and/or debris P are buried may be rotated below the second mount block 140.

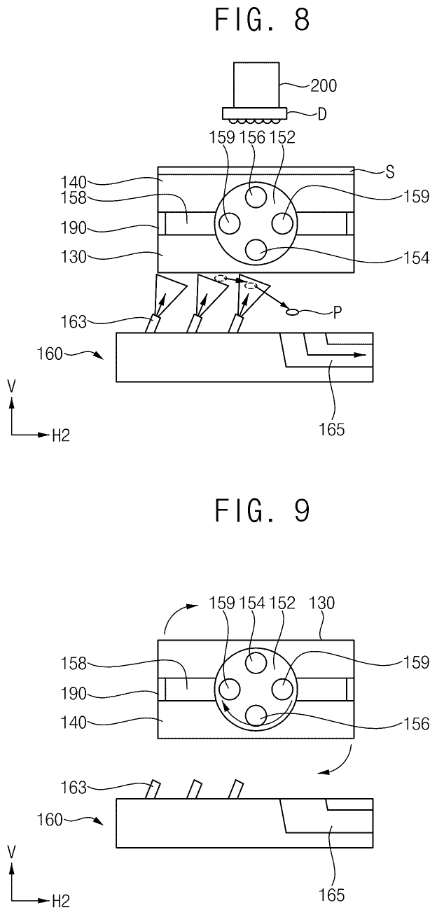

Referring to FIG. 8, the second holding surface 142 of the second mount block 140 may hold the package substrate S using vacuum pressure. The mount head 200 may attach, mount, and/or hold the semiconductor die D to the package substrate S held on the second holding surface 142.

During the die-attach operation, the cleaning module 160 may clean the first holding surface 132 of the first mount block 130. Specifically, the horizontal actuator 168 may move the cleaning block 162 along the second horizontal direction H2. While the horizontal actuator 168 moves along the second horizontal direction H2, the injection nozzles 163 may spray air onto the first holding surface 132 of the first mount block 130 to separate the particles and/or debris P from the first holding surface 132. The separated particles and/or debris P may be discharged from the cleaning block 162 through the suction groove 165.

Referring to FIG. 9, the rotation module 150 may rotate the first mount block 130 and the second mount block 140 by about 180° again. Accordingly, the first mount block 130 from which the particles and/or debris P are removed may be located on the second mount block 140.

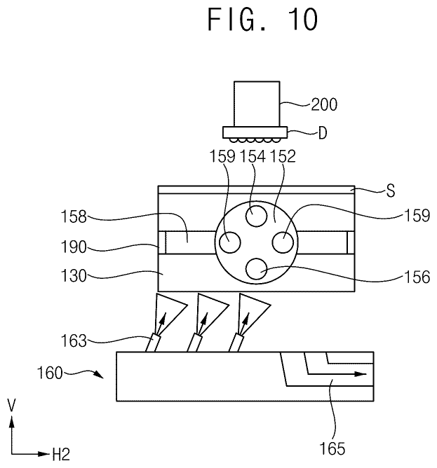

Referring to FIG. 10, the first holding surface 132 of the first mount block 130 may hold the package substrate S using vacuum pressure. The mount head 200 may attach the semiconductor die D to the package substrate S held on the first holding surface 132.

During this die-attach operation, the cleaning module 160 may clean the first holding surface 132 of the first mount block 130.

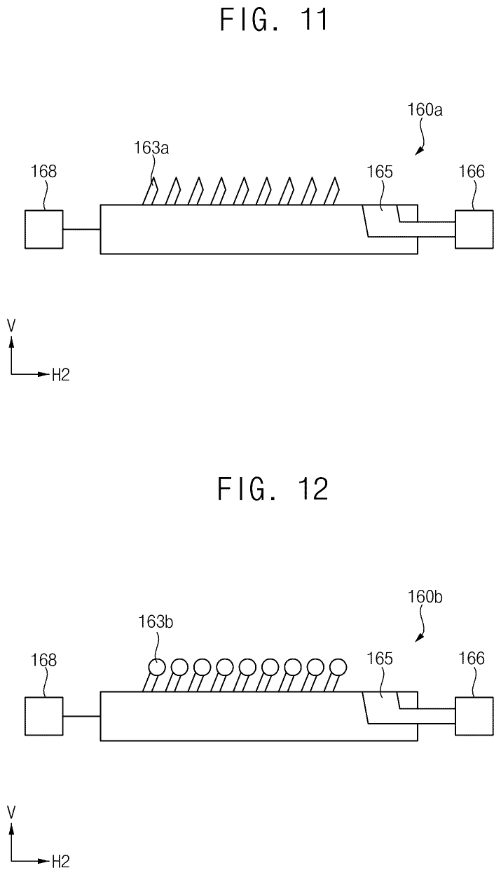

FIG. 11 is a cross-sectional view illustrating a cleaning module of a die attaching apparatus in accordance with at least one example embodiment.

Referring to FIG. 11, the cleaning module 160a of one or more example embodiments may include a plurality of blades 163a instead of the injection nozzles 163 of FIG. 4. The blades 163a may be in friction contact with the holding surface in order to remove particles and/or debris from the holding surface. In some example embodiments, the blades 163a may be arranged to be inclined and/or angled with respect to the vertical direction V, but are not limited thereto.

FIG. 12 is a cross-sectional view illustrating a cleaning module of a die attaching apparatus in accordance with at least one example embodiment.

Referring to FIG. 12, the cleaning module 160b of one or more example embodiments may include a plurality of brushes 163b instead of the injection nozzles 163 of FIG. 4. The brushes 163b may be in rotational contact with the holding surface in order to remove particles and/or debris from the holding surface.

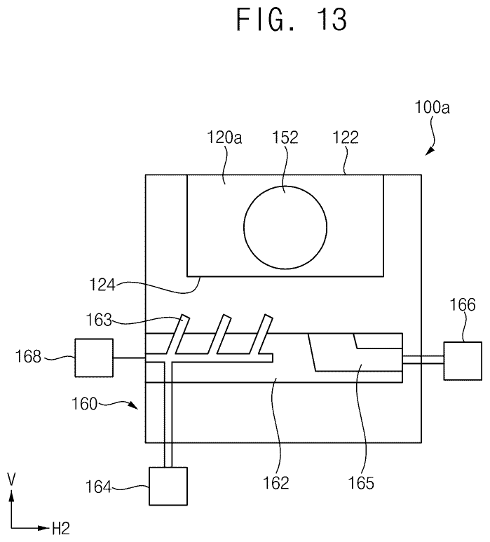

FIG. 13 is a cross-sectional view illustrating a die attaching apparatus in accordance with at least one example embodiment.

A die attachment device 100a of one or more example embodiments may include elements substantially the same as those of the die attachment device 100 shown in FIG. 1 except for a mount block. Accordingly, the same reference numerals may refer to the same elements and any further illustrations with respect to the same elements may be omitted herein for clarity and brevity.

Referring to FIG. 13, a mount block 120a of one or more example embodiments may include one block. That is, the first mount block 130 and the second mount block 140 in FIG. 1 may be combined to form the mount block 120a in FIG. 13.

Accordingly, the mount block 120a of one or more example embodiments may have a first surface and a second surface opposite to each other. The first holding surface 122 may correspond to the first surface, and the second holding surface 124 may correspond to the second surface. The first vacuum line may be connected to the first holding surface 122. The second vacuum line may be connected to the second holding surface 124.

The rotation shaft 152 of the rotation module 150 may be inserted into the center of the mount block 120a in the first horizontal direction H1. Accordingly, the entire mount block 120a may be rotated around the first horizontal direction H1 by the rotation of the rotation shaft 152. That is, the rotation module 150 may rotate the mount block 120a by approximately 180° around the rotation shaft 152 extending along the first horizontal direction H1.

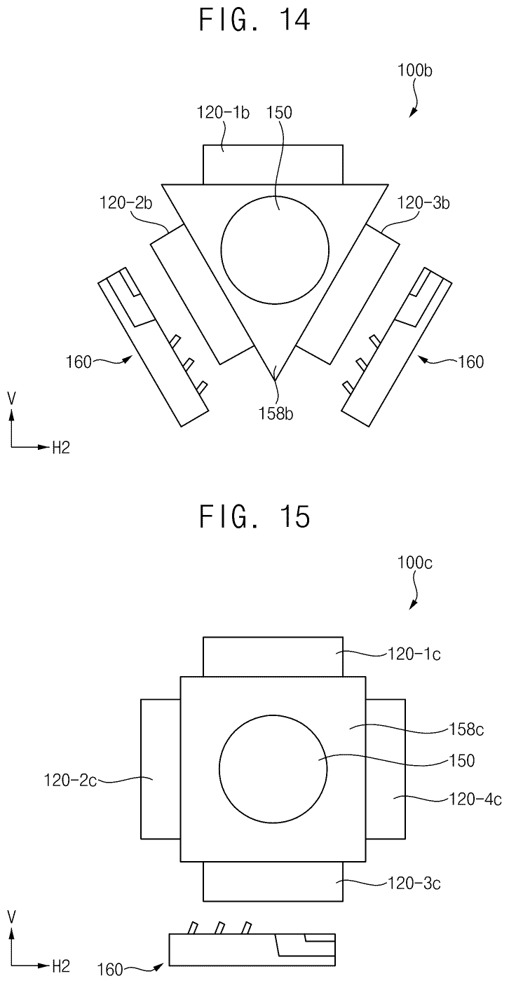

FIG. 14 is a cross-sectional view illustrating a die attaching apparatus in accordance with at least one example embodiment.

A die attachment device 100b of one or more example embodiments may include elements substantially the same as those of the die attachment device 100 shown in FIG. 1 except for a mount block. Accordingly, the same reference numerals may refer to the same elements and any further illustrations with respect to the same elements may be omitted herein for clarity and brevity.

Referring to FIG. 14, a mount block of one or more example embodiments may include a first mount block 120-1b, a second mount block 120-2b, and a third mount block 120-3b, but is not limited thereto, and for example, the die attachment device 100c may include a greater or lesser number of mount blocks.

The first mount block 120-1b may have a first holding surface. The second mount block 120-2b may have a second holding surface. The third mount block 120-3b may have a third holding surface.

The first mount block 120-1b, the second mount block 120-2b, and the third mount block 120-3b may be located at approximately 120° intervals around an axis extending along the first horizontal direction H1. In addition, the first mount block 120-1b, the second mount block 120-2b, and the third mount block 120-3b may have shapes and sizes compatible with each other, but are not limited thereto.

The first mount block 120-1b, the second mount block 120-2b, and the third mount block 120-3b may be connected to the rotation shaft 152 via the connection block 158b, and the rotation shaft 152 may extend along the first horizontal direction H1. The connection block 158b may have an equilateral triangular shape, but is not limited thereto.

In addition, at least one first damper may be interposed between the first mount block 120-1b and the second mount block 120-2b, at least one second damper may be between the second mount block 120-2b and the third mount block 120-3b, and at least one third damper may be between the third mount block 120-3b and the first mount block 120-1b.

The first vacuum line may be connected to the first holding surface of the first mount block 120-1b. The second vacuum line may be connected to the second holding surface of the second mount block 120-2b. The third vacuum line may be connected to the third holding surface of the third mount block 120-3b.

The rotation module 150 may rotate the first mount block 120-1b, the second mount block 120-2b, and the third mount block 120-3b by approximately 120° increments with respect to the rotation shaft 152 extending along the first horizontal direction H1.

The cleaning module 160 may clean at least one of the first mount block 120-1b, the second mount block 120-2b, and the third mount block 120-3b. For example, when the die attach process may be performed on the first mount block 120-1b, the cleaning module 160 may clean at least one of the second mount block 120-2b and the third mount block 120-3b.

FIG. 15 is a cross-sectional view illustrating a die attaching apparatus in accordance with at least one example embodiment.

A die attachment device 100c of one or more example embodiments may include elements substantially the same as those of the die attachment device 100 shown in FIG. 1 except for the mount block. Accordingly, the same reference numerals may refer to the same elements and any further illustrations with respect to the same elements may be omitted herein for clarity and brevity.

Referring to FIG. 15, a mount block of one or more example embodiments may include a first mount block 120-1c, a second mount block 120-2c, a third mount block 120-3c, and/or a fourth mount block 120-4c, etc., but is not limited thereto, and for example, the die attachment device 100c may include a greater or lesser number of mount blocks.

The first mount block 120-1c may have a first holding surface. The second mount block 120-2c may have a second holding surface. The third mount block 120-3c may have a third holding surface. The fourth mount block 120-4c may have a fourth holding surface.

The first mount block 120-1c, the second mount block 120-2c, the third mount block 120-3c, and the fourth mount block 120-4c may be arranged at approximately 90° intervals around an axis extending along the first horizontal direction H1. In addition, the first mount block 120-1c, the second mount block 120-2c, the third mount block 120-3c, and the fourth mount block 120-4c may have shapes and sizes compatible with each other, but are not limited thereto.

The first mount block 120-1c, the second mount block 120-2c, the third mount block 120-3c, and the fourth mount block 120-4c may be connected to the rotation shaft 152 via the connection block 158c, and the rotation shaft 152 may extend along the first horizontal direction H1. The connection block 158c may have a square shape, but may not be limited thereto.

In addition, at least one first damper may be interposed between the first mount block 120-1c and the second mount block 120-2c, at least one second damper may be between the second mount block 120-2c and the third mount block 120-3c, at least one third damper may be between the third mount block 120-3c and the fourth mount block 120-4c, and at least one fourth damper may be between the fourth mount block 120-4c and the first mount block 120-1c, etc.

The first vacuum line may be connected to the first holding surface of the first mount block 120-1c. The second vacuum line may be connected to the second holding surface of the second mount block 120-2c. The third vacuum line may be connected to the third holding surface of the third mount block 120-3c. The fourth vacuum line may be connected to the fourth holding surface of the fourth mount block 120-4c.

The rotation module 150 may rotate the first mount block 120-1c, the second mount block 120-2c, the third mount block 120-3c, and the fourth mount block 120-4c by 90° around the rotation shaft 152.

The cleaning module 160 may clean at least one of the first mount block 120-1c, the second mount block 120-2c, the third mount block 120-3c, and the fourth mount block 120-4c. For example, when the die attach process is performed on the first mount block 120-1c, the cleaning module 160 may clean at least one of the second mount block 120-2c, the third mount block 120-3c, and the fourth mount block 120-4c.

According to one or more example embodiments, the cleaning module 160 may clean one of the holding surfaces of the mount block except for the holding surface holding the package substrate S. Since the operation of the cleaning module 160 may be performed during the die attach process, it may not be desired and/or necessary to stop the die attach process in order to remove the particles, debris, etc. Accordingly, the efficiency of the die attach process may be improved, the cleaning process of the die and/or jig is improved, etc.

The foregoing is illustrative of various example embodiments of the inventive concepts and is not to be construed as limiting thereof. Although a few example embodiments have been described, those of ordinary skill in the art will readily appreciate that many modifications are possible in the example embodiments without departing from the novel teachings and advantages of the example embodiments. Accordingly, all such modifications are intended to be included within the scope of the example embodiments as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

1. A jig for a die attach apparatus, the jig comprising:
at least one mount block including at least two holding surfaces, each of the at least two holding surfaces configured to,
hold a package substrate on which a semiconductor die is mounted, and
rotate around a rotation shaft extending along a first horizontal direction; and
a cleaning device configured to clean a target holding surface among the at least two holding surfaces, the target holding surface being a holding surface which faces the cleaning device among the at least two holding surfaces.

2. The jig of claim 1, wherein the mount block comprises a single mount block.

3. The jig of claim 2, wherein the at least two holding surfaces further comprise:
a first holding surface on a first surface of the mount block; and
a second holding surface on a second surface of the mount block opposite to the first surface of the mount block.

4. The jig of claim 3, wherein the mount block further comprises:
a first vacuum line configured to provide a first vacuum pressure to the package substrate through the first holding surface.

5. The jig of claim 3, wherein the mount block further comprises:
a second vacuum line configured to provide a second vacuum pressure to the package substrate through the second holding surface.

6. The jig of claim 1, wherein the mount block is a first mount block, the first mount block including a first holding surface;
the jig further includes a second mount block, the second mount block including a second holding surface; and
the first mount block and the second mount block are spaced 180° around the rotation shaft.

7. The jig of claim 6, wherein the first mount block and the second mount block have a same shape and size.

8. The jig of claim 6, wherein the first mount block further comprises:
a first vacuum line configured to provide a first vacuum pressure to the package substrate through the first holding surface.

9. The jig of claim 6, wherein the second mount block further comprises:
a second vacuum line configured to provide a second vacuum pressure to the package substrate through the second holding surface.

10. The jig of claim 6, further comprising:
at least one damper between the first mount block and the second mount block, the at least one damper configured to absorb vibration between the first mount block and the second mount block.

11. The jig of claim 1, wherein the mount block is a first mount block, the first mount block including the first holding surface;
the jig further includes,
a second mount block including a second holding surface, and
a third mount block including a third holding surface; and
the first mount block, the second mount block and the third mount block are spaced 120° around the rotation shaft.

12. The jig of claim 11, wherein the first mount block, the second mount block and the third mount block have a same shape and size.

13. The jig of claim 11, wherein the first mount block further comprises:
a first vacuum line configured to provide a first vacuum pressure to the package substrate through a first holding surface.

14. The jig of claim 11, wherein the second mount block further comprises:
a second vacuum line configured to provide a second vacuum pressure to the package substrate through a second holding surface.

15. The jig of claim 11, wherein the third mount block further comprises:
a third vacuum line configured to provide a third vacuum pressure to the package substrate through the third holding surface.

16. The jig of claim 11, further comprising:
at least one first damper between the first mount block and the second mount block;
at least one second damper between the second mount block and the third mount block; and
at least one third damper between the third mount block and the first mount block.

17. The jig of claim 1, wherein the mount block is a first mount block including a first holding surface;
the jig further comprises,
a second mount block including a second holding surface,
a third mount block including a third holding surface, and
a fourth mount block including a fourth holding surface; and
the first mount block, the second mount block, the third mount block and the fourth mount block are spaced 90° around the rotation shaft.

18. The jig of claim 17, wherein the first mount block, the second mount block, the third mount block and the fourth mount block have a same shape and size.

19. The jig of claim 17, wherein the first mount block further comprises:
a first vacuum line configured to provide a first vacuum pressure to the package substrate through the first holding surface.

20. The jig of claim 17, wherein the second mount block further comprises:
a second vacuum line configured to provide a second vacuum pressure to the package substrate through the second holding surface.

21-58. (canceled)
